(19) United States
(12) Patent Application Publication
(10) Pub. No.: US 2010/0085002 A1
(43) Pub. Date: Apr. 8, 2010

(54) ELECTRICAL MACHINE AND AN ELECTRICAL DRIVE WITH SUCH AN ELECTRICAL MACHINE

(76) Inventor: Axel Knauff, Munnerstadt (DE)

Correspondence Address: HENRY M FEIEREISEN, LLC;HENRY M FEIEREISEN, 708 THIRD AVENUE, SUITE 1501, NEW YORK, NY, 10017, US

(21) Appl. No.: 12/374,200

(22) PCT Filed: Jul. 4, 2007
(86) PCT No.: PCT/EP07/56714

§ 371 Date: Aug. 24, 2009

(30) Foreign Application Priority Data
Jul. 17, 2006 (DE) 10 2006 032 974.0

(51) Int. Cl. G01R 31/02; H02K 11/00

(52) U.S. Cl. 318/490; 310/68 C

(57) ABSTRACT

An electric machine (3) comprises a number of sensors (9) and a recorder unit (15) for the signals (SIG), recorded by the sensors (9). According to the invention, the recorder unit (15) comprises a web server unit (16) with at least one data interface. Corresponding sensor data (SD) may be read out with the sensor signals (SIG) from the recorder unit (15) via the data interface. The data interface is particularly a LAN, USB or Firewire data interface using a TCP/IP data transport protocol.

The present invention relates to an electrical machine having a number of sensors. The invention also relates to an electrical drive which has an electrical machine according to the invention and a power converter for supplying power to the electrical machine.

An electrical machine is particularly an electric motor or a generator. It may be an asynchronous or synchronous machine.

Frequently, electrical machines have sensors which are required for the purpose of monitoring and/or controlling the electrical machine. The sensors may be temperature sensors, vibration sensors, winding fracture sensors, phase rotation indicators or the like. The sensors are preferably mounted at locations in the electrical machine which require monitoring, such as in the winding overhang or in the region of the motor bearings.

The electrical machine may have a sensor electronics section for the purpose of conditioning the sensed sensor signals for measurement. The sensor electronics section may be accommodated in a machine housing or preferably in a terminal box on the electrical machine. It may also have an interface, such as an RS232 interface, for the purpose of reading the measured values sensed by the sensor electronics section.

A drawback of this is that a specific reading program, such as a monitor program, on a personal computer (PC) or on a computer is required for the purpose of reading the measured values from the sensor electronics section.

Electrical drives may comprise a power converter and an electrical machine. A power converter may also have a plurality of electrical machines connected to it. It is also possible for a plurality of power converters to supply power to one electrical machine. The power converter may be a converter, an inverter or a rectifier, for example.

The power converter usually has a control unit for actuating a power section having one or more power converter modules. A power converter module typically comprises electronic switching means, such as power transistors, for producing a rotating field for the electrical machine.

The control unit may also be a standalone device which is connected to one or more power converter modules. In addition, the control unit is connected to the sensors of the electrical machine, described at the outset, for the purpose of monitoring and/or controlling the electrical machine.

The power converter may be connected to the electrical machine via a power connection cable and also via a sensor cable for connecting the sensors. For the purpose of connection, the electrical machine usually has a terminal box. This allows the respective line ends of the motor connection cable or of the sensor cable to be put onto appropriate terminals. The power connection cable and the sensor cable may also be combined in a common connecting cable.

The control unit may have a plurality of signal connections for connecting the sensors and also a downstream measurement sensing unit. The control unit of the power converter may have one or more data interfaces for communication with a superordinate control center in a production or automation system or an installation. The data interface may be a Profibus or CAN bus data interface, for example.

The data interface may also be a TCP/IP data interface for transmitting data via the Internet or via a company intranet. In this case, the data to be transmitted are preferably based on a standardized HyperText Transfer Protocol (HTTP). The HyperText Transfer Protocol is a protocol particularly for transmitting data via a network. It is used primarily for loading web pages and other data from the data network of the “World Wide Web” (WWW) using a web browser.

If a control unit has one or more TCP/IP data interfaces, these can be used to read diagnosis data or measurement data from the sensors of the electrical machine. By way of example, a PC or a notebook can be connected to the data interface as a reading device. For the purpose of connection, a TCP/IP data interface typically has a LAN (Local Area Network) socket, such as an RJ45 socket.

The TCP/IP interfaces described above may be part of a web server unit which can provide web pages upon request. A web server in the narrower sense is a software application for performing server service which provides information using the HTTP protocol.

In the case of an electrical drive or an electrical machine, the web pages may contain machine-specific measured values or status information. To this end, the web server unit is connected to a measuring unit in the control unit for data processing purposes. A service expert can then access appropriate web pages of the control unit during diagnosis using a standard web browser. A standard web browser is Internet Explorer from the Microsoft company, for example. A web page can be called by inputting what is known as a URL (Uniform Resource Locator) address or a link, for example, which address or link refers to the desired web page.

A drawback of the drives described above is that if the control unit fails then it is not possible to access the sensors in the electrical machine for data processing purposes.

it is an object of the invention to specify an electrical machine which provides a simple way of reading the machine sensor data.

It is a further object of the invention to specify a suitable drive.

The object is achieved with an electrical machine which has a number of sensors and a sensing unit for the sensor signals sensed by the sensors.

In a characteristic manner, the sensing unit has a web server unit having at least one data interface. Sensor data corresponding to the sensor signals can be read from the sensing unit via the data interface.

This has the associated advantage that a standard web browser can be used to read machine sensor measurement data directly from the electrical machine. The web browser is usually part of a piece of standard software on a PC or a computer.

A further advantage is that web browsers are already available for a multiplicity of computer operating systems, such as Windows, Linux, Unix or Mac OS.

The web server unit typically comprises a web service or a web server as a software application which is executed on a microprocessor or on a microcontroller. For the purpose of connecting a PC or computer, the web server unit has a LAN socket based on an IEEE 802.3 standard, for example. Alternatively, the web server unit may have a USB (Universal Serial Bus) socket or a Firewire socket based on an IEEE 1394 standard. Other connections in the form of sockets or plugs are also possible.

A web server unit of this kind is available as a physical unit from the LANTRONIX company (www.lantronix.com) under the type designation XPort, for example. This is a large scale integration physical unit which corresponds approximately to the dimensions of two LAN sockets. This physical unit incorporates a LAN socket and also a microcontroller for executing the web server. In addition, the web server unit has an electronic memory for storing the web pages. The web pages can be uploaded from a web browser via the LAN socket.

In addition the web server unit has a programmable SPI (Serial Port Interface) interface for connection to a processor-assisted unit, such as to a microcontroller or to a microprocessor. Using the SPI interface, the web server unit can read in and further process the sensor data sensed by the sensing unit. Preferably, the SPI interface is connected to three input/output pins or what are known as SPI ports on a microcontroller or microprocessor. The hardware and software complexity for the serial interface is minimal.

On the basis of a web server unit of this kind, an extremely compact sensing unit for sensing the sensor signals corning from the sensors in the electrical machine is possible. The sensing unit can be mounted at virtually any location in the electrical machine, such as in free spaces in the region of the winding overhang or the end shield.

The sensing unit preferably has a socket connector or terminal strip for connecting the line ends of the sensors. The line ends of the sensors may alternatively have a standard plug or a standard socket which can be plugged into a respective mating piece on the sensing unit.

The sensing unit is preferably a populated printed circuit board on which particularly the web server unit, a microcontroller, components for sensor signal sensing and also a power supply are arranged. It is also possible for a plurality of components or all the components of the sensing unit to be integrated in a single electronic component. Furthermore, sockets or terminals for connecting the sensors may be present.

In line with one preferred embodiment of the invention, the sensor data can be read by calling at least one web page on the web server unit. The web page is advantageously called by a standard web browser which is installed on a PC or on a computer. A web page can be called by inputting a URL address or by clicking on an appropriate link within the displayed web page, for example.

The web server unit may also provide one or more dynamic web pages which are generated only upon request by the web browser. The web browser then starts an application which allows current measurement data from the sensors to be read from the sensing unit via the SPI data interface. A subsequently generated dynamic web page advantageously has the current measured values from the sensors.

In line with one particular embodiment, the sensing unit has a data store for storing a chronological succession of sensor data. This advantageously allows even sensor data which have been captured earlier to be read. On the basis of the sensor data, simplified error analysis, for example when the electrical machine fails, is possible.

The sensor data can be stored in a chronological order in the manner of a history, for example. The data store can also be operated as a cyclic store, which is overwritten again after a prescribable memory cycle time. The memory cycle time can also be chosen individually for each sensor type.

In particular, the at least one data interface of the web server unit has a data transport protocol based on a TCP/IP standard. The TCP/IP data transport protocol can be supported both by the LAN interface and by the USB or Firewire data interface.

In a further embodiment, the electrical machine has a power connection which is in the form of a terminal box. The terminal box is used particularly for connecting electrical lines carrying large currents. In line with the invention, the sensing unit is accommodated in the terminal box.

The advantage is that the sensing unit can easily be replaced in the event of a technical defect.

A further advantage is that the sensing unit in the terminal box is protected against environmental influences such as dust and moisture. When the sensing unit is accommodated, a prescribed minimum voltage distance from voltage-carrying terminals needs to be maintained in the terminal box.

As a result of a further embodiment, at least one of the data interfaces is in the form of a standard connection for connecting a reading device. The reading device is a PC or a computer, for example. It may also be a control computer or a control unit, e.g. for a power converter. The connection may be a LAN socket, such as an RJ-45 socket. An appropriate LAN cable with an appropriate LAN plug can be plugged into the LAN socket for the purpose of reading the sensing unit.

Alternatively or in addition, at least one of the data interfaces may be in the form of a USB or Firewire socket.

In line with one particular embodiment, at least one standard connection is mounted in or on the terminal box.

This means that the connection is easily accessible. Preferably, the connection, such as the LAN, USB or Firewire socket, ends flush with an outer side of the terminal box. A cover may also be provided for the connection socket to protect against dirt and moisture.

Alternatively or in addition, at least one of the data interfaces of the web server unit may be a radio data interface.

This has the associated advantage that no data transmission cables are required for reading the web server unit. It is possible to read the data if a reading device with a suitable radio data interface is situated close to the electrical machine.

Preferably, the radio data interface is a WLAN (Wireless Local Area Network) radio data interface based on an IEEE 802.11 standard. The data transport protocol of the radio data interface is based on the TCP/IP standard.

The radio data interface may alternatively also be a Bluetooth radio data interface based on an IEEE 802.15.1 standard. Other radio data interfaces may be based on a GSM, UMTS or DECT standard, for example.

In particular, the radio data interface is, in line with a further embodiment, mounted in or on the terminal box.

The terminal box is preferably manufactured from a plastic, particularly from a plastic which is permeable to radio waves. The radio data interface is also arranged in the terminal box or on the sensing unit such that a preferred radio emission is possible away from the electrical machine.

In line with a further embodiment, the sensing unit has an associated electrical energy store for electrical backup for the sensing unit. The energy store may be a battery or a storage battery, for example.

This has the associated advantage that the sensing unit, including the web server unit, can continue to be operated if an external power supply for the sensing unit fails. When operating properly, the sensing unit can be supplied with power via an external power supply unit, for example.

In one preferred embodiment, the sensing unit can be connected to a power supply for supplying power to the sensing unit via at least one of the data interfaces.

This makes it possible to dispense with a separate power supply, such as the power supply unit.

In the case of a LAN socket, it is advantageous if two of the eight socket contacts which are not used for the data transmission are used for supplying power. The supply current is then preferably supplied via the reading device.

In the case of a USB or Firewire socket, provision is already made for the transmission of a supply current. The supply current is supplied by the reading device via the corresponding USB or Firewire connection socket.

The sensors are particularly a temperature sensor, a vibration sensor and/or a phase rotation indicator. The sensor may also be a winding fracture sensor or a brake monitoring sensor.

In particular, the electrical machine is an electric motor. The electrical machine may alternatively, or according to its mode of operation, also be a generator.

The object of the invention is also achieved with an electrical drive which has an electrical machine according to the invention and a power converter for supplying power to the electrical machine. The power converter has a control unit which comprises a web server unit having at least one data interface. A respective one of the power-converter and machine data interfaces are connected to one another for the purpose of reading the sensor data.

The particular advantage is that the entire sensor system of the electrical machine can easily be linked into the control unit of the power converter or of the drive for data processing purposes. To this end, the web server of the control unit accesses one or more referenceable web pages of the web server unit in the electrical machine.

A further advantage is that if the control unit of the drive fails then it is still possible to access the sensors in the electrical machine for data processing purposes. In this case, a reading device, such as the PC or the notebook can be connected to the sensing unit in the electrical machine for data processing purposes.

Preferably, the sensing unit has two data interfaces. The first of the two data interfaces connects the sensing unit to the power converter or to the control unit. If the drive fails, the reading device can be connected to the sensing unit via the second data interface for the purpose of diagnosis for the electrical machine.

In one particular embodiment, the control unit of the power converter has an electrical power supply. The power supply is connected to the sensing unit of the electrical machine via a respective one of the power-converter and machine data interfaces.

The advantage is that a separate power supply is not required for the sensing unit and for the web server unit.

Further advantageous embodiments and preferred developments of the invention can be found in the subclaims.

The invention and advantageous embodiments thereof are described in more detail below with reference to the figures which follow, in which

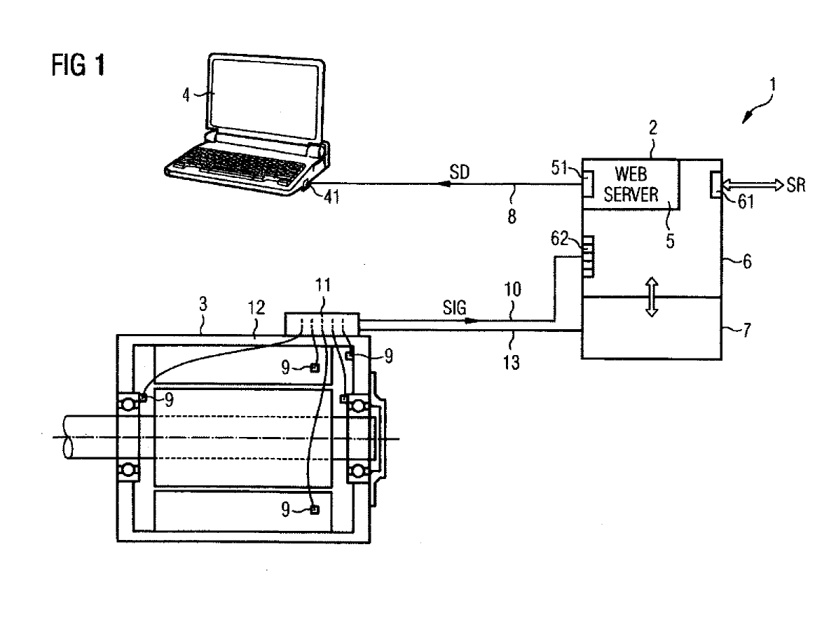

FIG. 1 shows an electrical drive with a power converter, an electrical machine and a reading device for reading sensor data in accordance with the prior art,

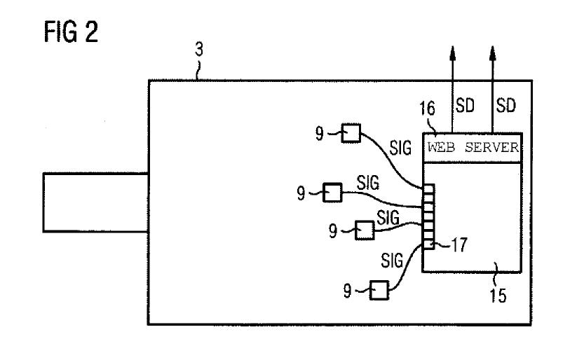

FIG. 2 shows a schematic illustration of an electrical machine according to the invention,

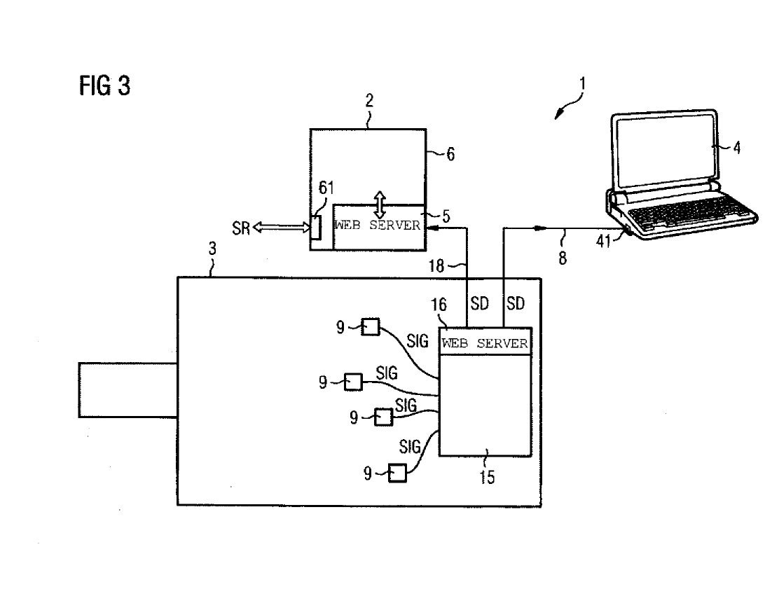

FIG. 3 shows a schematic illustration of the design of a drive according to the invention by way of example, and

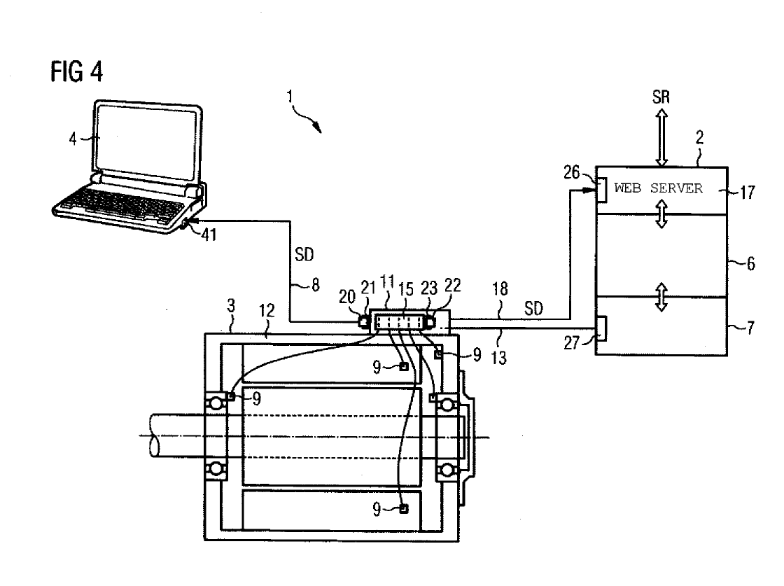

FIG. 4 shows the drive shown in FIG. 3 with the electrical machine according to the invention in detail.

FIG. 1 shows an electrical drive 1 with a power converter 2, at least one electrical machine 3 and a reading device 4 for reading sensor data SD in accordance with the prior art.

The sensor data SD are conditioned sensor signals SIG which come from sensors 9 and which are accommodated for monitoring and/or control purposes in the electrical machine 3. The sensors 9 may be temperature sensors, e.g. for monitoring the bearing temperature or winding temperature. The sensors 9 may also be vibration sensors, phase rotation indicators, winding fracture sensors and the like.

The power converter 2 may be a converter, rectifier or inverter, for example. It has a control unit 6, particularly for monitoring and controlling a power section 7 and the electrical machine 3 connected thereto, for example. The power section 7 may be a pulse-controlled inverter, for example.

The control unit 6 has a power-converter web server unit 5, for example, which is connected to the control unit 6 of the power converter 2 via an internal data link. The control unit 6 is typically a processor-assisted data processing unit. In the example in FIG. 1, the web server unit 5 has a data interface with a connection socket 51. The data interface can be used to read the sensor data SD, e.g. for diagnosis for the electrical machine 3.

The power-converter web server unit 5 usually has a processor-assisted unit for performing a server service on a web server. The web server provides selected web pages upon request by a web browser. In this case, the control unit 6 can condition the sensed sensor signals SIG in the form of HTTP files and provide them to the web server.

The reading device 4 is a mobile notebook, for example. It can be connected to the power-converter web server unit 5 via an interface cable 8 for the purpose of transmitting the sensor data SD. The data transmission between the reading device 4 and the web server unit 5 or the control unit 6 may be based on a TCP/IP data transport protocol, for example. The web browser is usually part of the standard software of the reading device 4.

In addition, the control unit 6 is connected to the respective sensors 9 in the electrical machine 3 via a sensor cable 10 for the purpose of sensing measured values. The sensor cable 10 usually has a multiplicity of signal lines. The respective ends of the signal lines in the example in FIG. 1 have been placed on a terminal strip 62 of the control unit 6 and on terminals—not shown in more detail—of a machine terminal box 11. The terminal box 11 is usually mounted on an outer side of a machine housing 12 of the electrical machine 3. From there, the signal lines are connected up to the respective sensors 9.

The terminal box 11 typically has a motor cable 13 connected in it which has some motor lines for supplying power to the electrical machine 3. The motor lines are connected to appropriate power outputs of the power section 7 of the power converter 2.

As FIG. 1 also shows, the control unit 6 is connected to a control computer SR—not shown in more detail—via a further data interface 61 of the control unit 6. The control computer SR may be an installation controller or a process computer, for example, which controls the drive in combination with further installation components.

FIG. 2 shows a schematic illustration of an electrical machine 3 in accordance with the invention. The electrical machine 3 accommodates a number of sensors 9 and also a sensing unit 15 for sensor signals SIG sensed by the sensors 9.

In the example in the present FIG. 2, the electrical machine 3 is an electric motor. It may alternatively be a generator. It may also be a synchronous or asynchronous machine. In the case of an electric motor, it may be a rotating electric motor or a linear motor.

The sensors 9 are essentially the same as in the case of the example of the prior art shown in FIG. 1. The sensing unit 15 preferably has a terminal strip 17 in which the respective sensor lines of the sensors 9 can be placed or plugged in.

In line with the invention, the sensing unit 15 senses the sensor signals SIG and converts them into sensor data SD which correspond to the sensor signals SIG. The sensing unit 15 can digitize, amplify or filter the sensor signals SIG, for example. Furthermore, the sensing unit 15 may have a data store for storing a chronological succession for the sensor data SD. This allows access to earlier sensor data SD for data processing purposes.

The sensing unit 15 also has a web server unit 16 with, by way of example, two data interfaces 17. It may also have only one data interface or more than two data interfaces.

The web server is essentially a software application which is executed on a processor unit of the web server unit 16, such as a microcontroller. The web server or the web services can alternatively also be executed on a processor or on a microcontroller of the sensing device 15. Alternatively, the web server unit 16 may be an integrated electronic component, such as the integrated chip XPort from the LANTRONIX company, which has means for performing the server service.

The data interface preferably supports a data transport protocol based on a TCP/IP standard. The sensor data SD can be read via the data interface by calling at least one web page on the web server unit 16. The web pages are preferably based on an HTTP standard. This allows the sensor data SD, for example during a diagnosis, to be read independently of a control unit 6 in a power converter 2 or of another superordinate control computer SR.

For the purpose of reading the sensor data SD, the reading device 4 or the control unit 6 of the power converter 2 is connected to the electrical machine 3 or to the sensing unit 15, for example. One or more web pages with the desired sensor data SD can be called using a web browser, for example, which shows the received web pages on a display. The web pages can also be loaded by a monitoring and control application of the control unit 6 and evaluated in terms of relevant sensor data SD for monitoring and regulating the electrical machine 3.

FIG. 3 shows a schematic illustration of the design of a drive 1 according to the invention by way of example.

The drive 1 has a power converter 2 and also an electrical machine 3 according to the invention. The power converter 2 has a control unit 6 for monitoring and/or controlling the connected electrical machine 3. The control unit 6 may also be designed to monitor and/or control a plurality of electrical machines 3.

The control unit 6 comprises a control-unit or power-converter web server unit 5 having, by way of example, a data interface. The data interface is connected to the data interface of the electrical machine 3 via a data cable 18. The latter allows the web server unit 5 to read in the sensor data SD coming from the electrical machine 3.

The right-hand portion of FIG. 3 shows a reading device 4 in the form of a notebook. For the purpose of reading the sensor data SD, such as for the purpose of diagnosis for the electrical machine, the reading device 4 and the electrical machine 3 or the sensing unit 15 are connected via an interface cable 8.

In the example in FIG. 3, the control unit 6 has a further data interface 61. This is used for the data transmission between the control unit 6 and a superordinate control computer SR. Alternatively or in addition, the further data interface may be a data interface of the web server unit 5.

FIG. 4 shows the drive 1 shown in FIG. 3 with the electrical machine 3 according to the invention in detail.

The electrical machine 3 shown has a power connection, in the form of a terminal box 11, for the purpose of connecting the electrical machine 3. The motor connecting cable 18 connects a power section 7 of the power converter 2 to the terminal box 11 of the electrical machine 3. The motor connecting cable 18 typically has a few motor lines which are put onto appropriate power terminals in the terminal box 11.

The terminal box 11 also accommodates the sensing unit 15. The sensing unit 15 may be a populated printed circuit board. Preferably, the sensing unit 15 is of encapsulated design in order to protect it against contact and against dirt. To facilitate connection of the sensor lines, it is advantageous if the sensing unit 15 has appropriate terminal strips or socket connectors.

In the example in FIG. 4, the sensing unit 15 has two data interfaces which are in the form of a standard connection for connecting a reading device 4, 6. Preferably, the standard connection is a LAN, USB or Firewire socket 21, 23. The reference symbol 20, 22 denotes the respective plug on the data cable 18 or on the interface cable 8 for connecting the electrical machine 3 to the power converter 2 or to the reading device 4.

The data interface of the web server unit 16 in the sensing unit 15 may alternatively or additionally be a radio data interface. In this case, it is possible to dispense with a cabled connection option. The sensor data SD can then be transmitted when a reading device 4, such as a notebook, with a suitable radio data interface is in range of the electrical machine 3. Preferably, the radio data interface is based on a WLAN standard.

The radio data interface may also be mounted in or on the terminal box 11. Preferably, a transmission/reception antenna of the radio data interface is oriented such that a radio emission direction away from the electrical machine 3 is possible. This significantly reduces interfering influences as a result of the predominantly metal components of the electrical machine 3.

For the purpose of electrical backup for the sensing unit 15 and for the web server unit 16, the sensing unit 15 may have an electrical energy store, such as a storage battery or battery. This ensures an uninterrupted supply of power should an external power supply for the sensing unit 15 fail.

It is particularly advantageous if the sensing unit 15 is connected to a power supply for supplying power to the sensing unit 15 via at least one of the data interfaces thereof.

If the data interface is a LAN interface with an appropriately configured 8-pin LAN socket, it is possible to use two of the eight socket contacts which are not used for data transmission, for example, for supplying power. The supply current is then supplied via the reading device 4, 6. By way of example, the power-converter data interface of the control unit 6 may have an internal power supply unit for providing the supply current. The power supply lines of the power supply unit need to be connected to corresponding free socket contacts of the connection socket 26 of the web server unit 17 of the control unit 6.

In the case of a USB or Firewire socket as connection socket for the data interfaces, provision is already made for a supply current to be transmitted. The supply current is supplied by the reading device via the corresponding USB or Firewire connection socket.

1.-15. (canceled)

16. An electric motor, comprising:
a plurality of sensors; and
a measurement sensing unit, integrated in the electric motor, for sensor signals sensed by the sensors, wherein the measurement sensing unit has at least one data interface to read sensor data corresponding to the sensor signals from the measurement sensing unit, wherein the measurement sensing unit has a web server unit.

17. The electric motor of claim 16, wherein the sensor data is read by calling at least one web page on the web server unit.

18. The electric motor of claim 16, wherein the measurement sensing unit has a data store for storing a chronological succession of sensor data.

19. The electric motor of claim 16, wherein at least one data interface supports a data transport protocol based on a TCP/IP standard.

20. The electric motor of claim 16, further comprising a power connection constructed in the form of a terminal box for connecting the electric motor, said measurement sensing unit being accommodated in the terminal box.

21. The electric motor of claim 16, wherein at least one data interface is constructed in the form of a standard connection for connecting a reading device.

22. The electric motor of claim 21, further comprising a power connection constructed in the form of a terminal box for connecting the electric motor, said standard connection being mounted in or on the terminal box.

23. The electric motor of claim 16, wherein at least one data interface of the web server unit is a radio data interface.

24. The electric motor of claim 23, further comprising a power connection constructed in the form of a terminal box for connecting the electric motor, said radio data interface being mounted in or on the terminal box.

25. The electric motor of claim 16, further comprising an electrical energy store operatively connected to the measurement sensing unit for electrical backup for the measurement sensing unit.

26. The electric motor of claim 16, wherein the measurement sensing unit is connected to a power supply for supplying power to the measurement sensing unit via at least one data interface.

27. The electric motor of claim 16, wherein one of the sensors is a temperature sensor, a vibration sensor or a phase rotation indicator.

28. An electrical drive, comprising:
an electric motor having a plurality of sensors, and a measurement sensing unit, integrated in the electric motor, for sensor signals sensed by the sensors, wherein the measurement sensing unit has at least one data interface to read sensor data corresponding to the sensor signals from the measurement sensing unit, wherein the measurement sensing unit has a web server unit; and
a power converter for supplying power to the electric motor, said power converter having a control unit which comprises a web server unit having at least one data interface,
wherein a data interface of the power-converter and a data interface of the electric-motor are connected to one another for reading the sensor data.

29. The electrical drive of claim 28, wherein the control unit of the power converter has an electrical power supply connected to the measurement sensing unit of the electric motor via a data interface of the power-converter and a data interface of the electric-motor.
